(19) United States
(12) Patent Application Publication
(10) Pub. No.: US 2024/0153852 A1
(43) Pub. Date: May 9, 2024

(54) SEMICONDUCTOR DEVICE AND IGNITION DEVICE

(71) Applicant: ROHM CO., LTD., Kyoto-shi (JP)

(72) Inventor: Yoshiaki SASAKI, Kyoto-shi (JP)

(21) Appl. No.: 18/411,899

(22) Filed: Jan. 12, 2024

Related U.S. Application Data
(63) Continuation of application No. PCT/JP2022/028455, filed on Jul. 22, 2022.

(30) Foreign Application Priority Data
Aug. 19, 2021 (JP) 2021-134295

(51) Int. Cl. H01L 23/495; H01L 25/16; H01L 23/00

(52) U.S. Cl. CPC H01L 23/49562; H01L 23/49582; H01L 25/162; H01L 24/32; H01L 24/48; H01L 24/49; H01L 2224/32245; H01L 2224/48111; H01L 2224/48175; H01L 2224/49171; H01L 2924/13055

(57) ABSTRACT

A semiconductor device includes a switching element, a first lead, and a metal plate. The first lead includes a lead obverse surface on which the switching element is mounted, and a lead reverse surface facing away from the lead obverse surface in a thickness direction. The metal plate overlaps with the switching element as viewed in the thickness direction, and is bonded to the first lead.

### TECHNICAL FIELD

The present disclosure relates to a semiconductor device and an ignition device. The present disclosure also relates to a method for manufacturing the semiconductor device.

### BACKGROUND ART

Conventionally, an ignition device including an ignition coil connected to a spark plug of an engine and a semiconductor device (igniter) that controls the current flowing through the ignition coil, has been known. JP-A-2019-163730 discloses an example of a conventional igniter. The igniter disclosed in this document controls the current flowing through a primary coil of an ignition coil according to an ignition command signal IGT (ignition timing) inputted from an engine control unit (ECU). The igniter includes a switch element for switching between a state of supplying current to the primary coil and a state of blocking the current supplied thereto. The switch element is mounted on a lead and covered with a sealing resin. Heat generated by the switch element is dissipated via the lead.

In addition to the switch element, the igniter further includes a control element for controlling the switch element, and a plurality of passive elements. However, there is a demand for downsizing such an igniter. Accordingly, it is difficult to increase the size of the lead on which the switch element is mounted. On the other hand, the switch element is desired to have a higher heat dissipation capability (dynamic heat dissipation capability).

### BRIEF DESCRIPTION OF THE DRAWINGS

FIG. 1 is a block diagram illustrating the overall configuration of a vehicle including a semiconductor device according to a first embodiment of the present disclosure.

FIG. 2 is a plan view illustrating the semiconductor device of FIG. 1.

FIG. 3 is a plan view illustrating the semiconductor device of FIG. 1, with a sealing resin shown transparent.

FIG. 4 is a right-side view illustrating the semiconductor device of FIG. 1.

FIG. 5 is a cross-sectional view taken along line V-V in FIG. 3.

FIG. 6 is a cross-sectional view taken along line VI-VI in FIG. 3.

FIG. 7 is a flowchart showing an example of a method for manufacturing the semiconductor device of FIG. 1.

FIG. 8 is a cross-sectional view illustrating a step in an example of a method for manufacturing the semiconductor device in FIG. 1.

FIG. 9 is a cross-sectional view illustrating a step in the example of the method for manufacturing the semiconductor device in FIG. 1.

FIG. 10 is a cross-sectional view illustrating a step in the example of the method for manufacturing the semiconductor device in FIG. 1.

FIG. 11 is a cross-sectional view illustrating a step in the example of the method for manufacturing the semiconductor device in FIG. 1.

FIG. 12 is a cross-sectional view illustrating a step in the example of the method for manufacturing the semiconductor device in FIG. 1.

FIG. 13 is a cross-sectional view illustrating a step in the example of the method for manufacturing the semiconductor device in FIG. 1.

FIG. 14 is a cross-sectional view illustrating a semiconductor device according to a second embodiment of the present disclosure.

FIG. 15 is a cross-sectional view illustrating a semiconductor device according to a third embodiment of the present disclosure.

FIG. 16 is a cross-sectional view illustrating a semiconductor device according to a fourth embodiment of the present disclosure.

FIG. 17 is a cross-sectional view illustrating a semiconductor device according to a fifth embodiment of the present disclosure.

FIG. 18 is a plan view illustrating a semiconductor device according to a sixth embodiment of the present disclosure, with a sealing resin shown transparent.

FIG. 19 is a cross-sectional view taken along line XIX-XIX in FIG. 18.

### DETAILED DESCRIPTION OF EMBODIMENTS

The following describes preferred embodiments of the present disclosure with reference to the drawings.

### First Embodiment

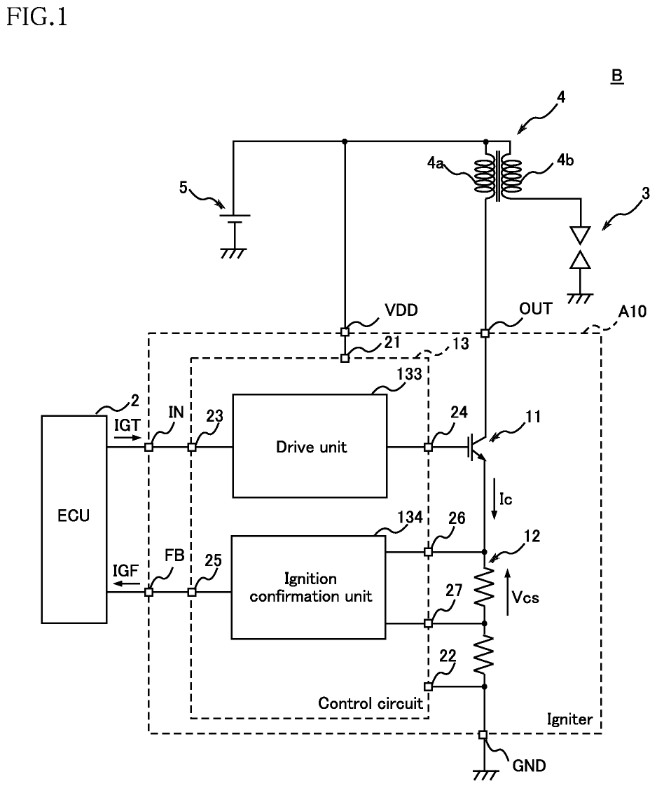

The following describes a semiconductor device A10 according to a first embodiment of the present disclosure, with reference to FIGS. 1 to 6. The present embodiment will be described with an example where the semiconductor device A10 is a so-called igniter. The igniter is a semiconductor device for controlling an ignition coil connected to a spark plug for an engine.

FIG. 1 is a block diagram showing the overall configuration of a vehicle B including the semiconductor device A10, which is an igniter. The vehicle B includes the semiconductor device A10, ECU 2, a spark plug 3, an ignition coil 4, and a battery 5. Note that the vehicle B also includes other constituent elements, which are omitted in FIG. 1. The semiconductor device A10 and the ignition coil 4 constitute an ignition device for igniting the spark plug 3.

The ECU 2 is an electronic control unit for controlling the operation of the engine, and is realized by a microcomputer including a CPU and a memory. The ECU 2 generates an ignition command signal IGT, which indicates the ignition timing of the spark plug 3 and serves as a periodic signal synchronized with the rotation of the engine. The ECU 2 outputs the ignition command signal IGT to the semiconductor device A10. The ECU 2 is an example of an “engine control device”.

The ignition coil 4 generates high voltage for discharging the spark plug 3. The ignition coil 4 includes a primary coil 4a and a secondary coil 4b. One terminal of the primary coil 4a is electrically connected to the battery 5, and the other terminal thereof is electrically connected to an output terminal OUT of the semiconductor device A10. One terminal of the secondary coil 4b is electrically connected to the battery 5, and the other terminal thereof is electrically connected to the spark plug 3.

The spark plug 3 is provided for each cylinder of the engine, which is not illustrated, and explodes a fuel-air mixture within the engine by discharge.

The semiconductor device A10 controls the discharge of the spark plug 3 according to the ignition command signal IGT inputted by the ECU 2. Specifically, the semiconductor device A10 controls a current Ic flowing through the primary coil 4a of the ignition coil 4 according to the ignition command signal IGT. The semiconductor device A10 supplies the current Ic to the primary coil 4a during a period in which the ignition command signal IGT is at a high level. Then, the semiconductor device A10 blocks the current Ic flowing through the primary coil 4a when the ignition command signal IGT switches from a high level to a low level. As a result, a back electromotive force of several hundred volts is generated in the primary coil 4a. At this point, a high voltage of several tens of kV, for example, resulting from multiplying the voltage at the primary side by a turn ratio, is generated in the secondary coil 4b. The spark plug 3 is discharged by the high voltage applied from the secondary coil 4b.

The semiconductor device A10 includes a power supply terminal VDD, a ground terminal GND, an input terminal IN, an output terminal OUT, and a feedback terminal FB. The power supply terminal VDD is electrically connected to the battery and supplied with a power supply voltage. The ground terminal GND is grounded. The input terminal IN is electrically connected to the ECU 2 via a harness that is not illustrated, and receives the ignition command signal IGT from the ECU 2. The output terminal OUT is electrically connected to the primary coil 4a of the ignition coil 4. The feedback terminal FB is electrically connected to the ECU 2 via a harness, and outputs an ignition confirmation signal IGF (Ignition Flag) to the ECU 2. The semiconductor device A10 further includes a switching element 11, a current sensing resistor 12, and a control circuit 13.

The switching element 11 is an insulated gate bipolar transistor IGBT, for example, and is turned on and off by the control circuit 13 to be electrically connected to or insulated from the output terminal OUT and the ground terminal GND. The collector terminal of the switching element 11 is electrically connected to the primary coil 4a of the ignition coil 4 via the output terminal OUT. The emitter terminal of the switching element 11 is grounded via the ground terminal GND. The gate terminal of the switching element 11 is electrically connected to the control circuit 13. The switching element 11 is turned on and off according to a gate drive signal inputted from the control circuit 13 to the gate terminal. Note that the switching element 11 is not limited to an IGBT, and may be another switching element such as a metal-oxide-semiconductor field-effect transistor (MOSFET).

The current sensing resistor 12 is connected between the emitter terminal of the switching element 11 and the ground terminal GND. Note that a resistor element of the current sensing resistor 12, which is connected in series to the side of the ground terminal GND in FIG. 1, indicates the parasitic resistance of a lead 42 (a lead having the ground terminal GND) described below. When the switching element 11 is turned on, the current sensing resistor 12 is supplied with the current Ic flowing through the primary coil 4a of the ignition coil 4. Accordingly, a detection voltage Vcs proportional to the current Ic is generated between the terminals of the current sensing resistor 12. The resistance value of the current sensing resistor 12 is approximately several mΩ to several tens of mΩ, for example. Thus, even if the current Ic flowing through the current sensing resistor 12 is several A to tens of A, the detection voltage Vcs is suppressed to several mV to several hundred mV. In the present embodiment, the current sensing resistor 12 is a resistance component of a bonding wire arranged in a current path between the emitter terminal of the switching element 11 and the ground terminal GND.

The control circuit 13 controls the semiconductor device A10, and is realized by a semiconductor element (a control element 20 described below) that is a function IC integrated on a semiconductor substrate. The control circuit 13 drives the switching element 11 according to the ignition command signal IGT inputted from the ECU 2. Furthermore, the control circuit 13 monitors the current Ic flowing through the primary coil 4a, generates the ignition confirmation signal IGF, and outputs the signal IGF thus generated to the ECU 2. The control circuit 13 also has other functions such as a current limiting function and a timer protection function, where the current limiting function limits the current Ic flowing through the switching element 11 to a predetermined upper limit or less and the timer protection function forcibly turns off the switching element 11 when a predetermined waiting period (e.g., approximately 100 ms) has elapsed while the ignition command signal IGT is maintained at a logic level of when the ignition command signal iGT is on.

The control circuit 13 includes a power supply pad 21, a ground pad 22, an input pad 23, a gate output pad 24, a feedback output pad 25, a sense input pad 26, and a sense ground pad 27. The power supply pad 21 is electrically connected to the power supply terminal VDD, and the ground pad 22 is electrically connected to the ground terminal GND. The input pad 23 is electrically connected to the input terminal IN, the gate output pad 24 is electrically connected to the gate terminal of the switching element 11, and the feedback output pad 25 is electrically connected to the feedback terminal FB. The sense input pad 26 is electrically connected to a high-potential terminal of the current sensing resistor 12. The sense ground pad 27 is electrically connected to a low-potential terminal of the current sensing resistor 12. Furthermore, the control circuit 13 includes a drive unit 133 and an ignition confirmation unit 134.

The drive unit 133 controls the switching element 11. The drive unit 133 controls on and off of the switching element 11 by controlling the voltage of the gate terminal of the switching element 11 according to the ignition command signal IGT inputted from the ECU 2. The drive unit 133 includes a high-frequency filter, a comparator, a delay circuit, and a driver, which are not illustrated. The high-frequency filter removes high-frequency noise from the ignition command signal IGT and outputs the signal IGT to the comparator. The comparator compares the ignition command signal IGT from which high-frequency noise has been removed to a threshold value, and determines a level of the signal IGT (whether it is a high level or a low level). The comparator outputs a determination signal indicating a result of the determination to the delay circuit. The delay circuit gives a predetermined delay to the determination signal and outputs the delayed determination signal to the driver. According to the determination signal, the driver generates and outputs a gate drive signal at a level capable of driving the switching element 11. The drive unit 133 turns on the switching element 11 during a period in which the ignition command signal IGT is at a high level, and turns off the switching element 11 during a period in which the ignition command signal IGT is at a low level. The switching element 11 switches from on to off when the ignition command signal IGT switches from a high level to a low level. As a result, a high voltage is generated in the secondary coil 4b of the ignition coil 4, and the high voltage is applied to the spark plug 3.

The ignition confirmation unit 134 generates and outputs the ignition confirmation signal IGF according to the current Ic flowing through the primary coil 4a. The ignition confirmation unit 134 compares the current Ic to reference currents Iref 1 and Iref 2 (>Iref 1) to generate the ignition confirmation signal IGF. In practice, the ignition confirmation unit 134 compares the voltage (detection voltage Vcs) between the terminals of the current sensing resistor 12 to the reference voltage Vref 1 corresponding to the reference current Iref 1, and to the reference voltage Vref 2 (>Vref 1) corresponding to the reference current Iref 2, and thereby generates the ignition confirmation signal IGF. The ignition confirmation unit 134 generates a signal that is at a first level (e.g., low level) when the detection voltage Vcs is between the reference voltage Vref 1 and the reference voltage Vref 2 (Vref 1<Vcs<Vref 2), and that is at a second level (e.g., high level) when the detection voltage Vcs is not between the reference voltages Vref 1 and Vref 2 (Vcs <Vref 1, Vref 2<Vcs), and outputs the signal as the ignition confirmation signal IGF to the ECU 2. Note that the first level may be the high level and the second level may be the low level.

The semiconductor device A10 is provided as a semiconductor integrated circuit device in which the switching element 11, the current sensing resistor 12, and the control circuit 13 are packaged. In the present embodiment, the semiconductor device A10 is of a small inline package (SIP) type. Note that the package type of the semiconductor device A10 is not limited to the SIP. The semiconductor device A10 includes a switching element 60, a control element 20, capacitors 14 and 16, a resistor 15, leads 41 to 48, a metal plate 49, bonding wires 51 to 59, and a sealing resin 7.

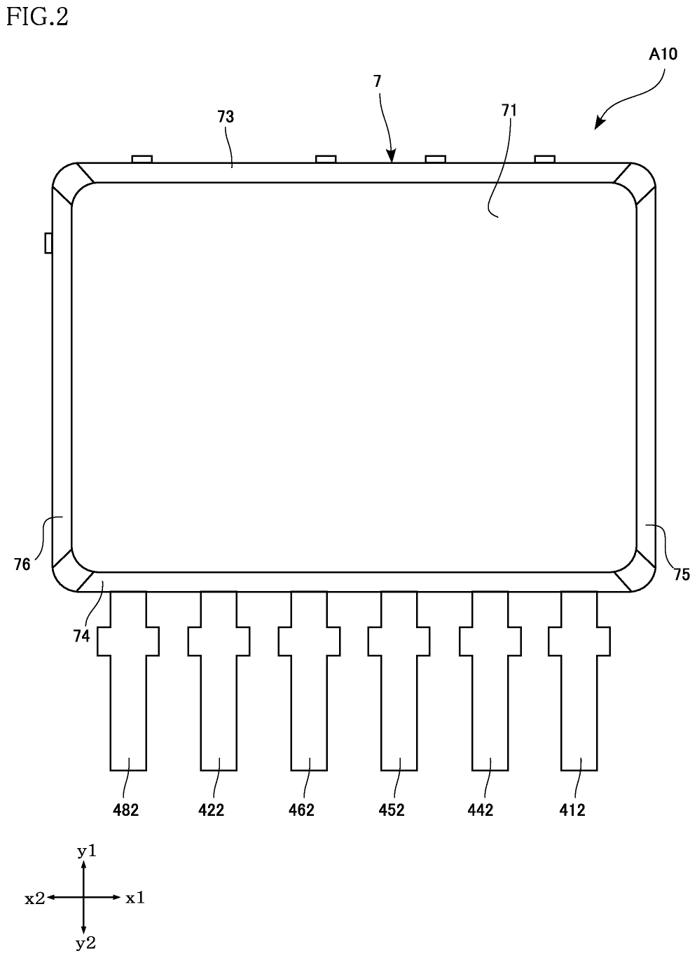

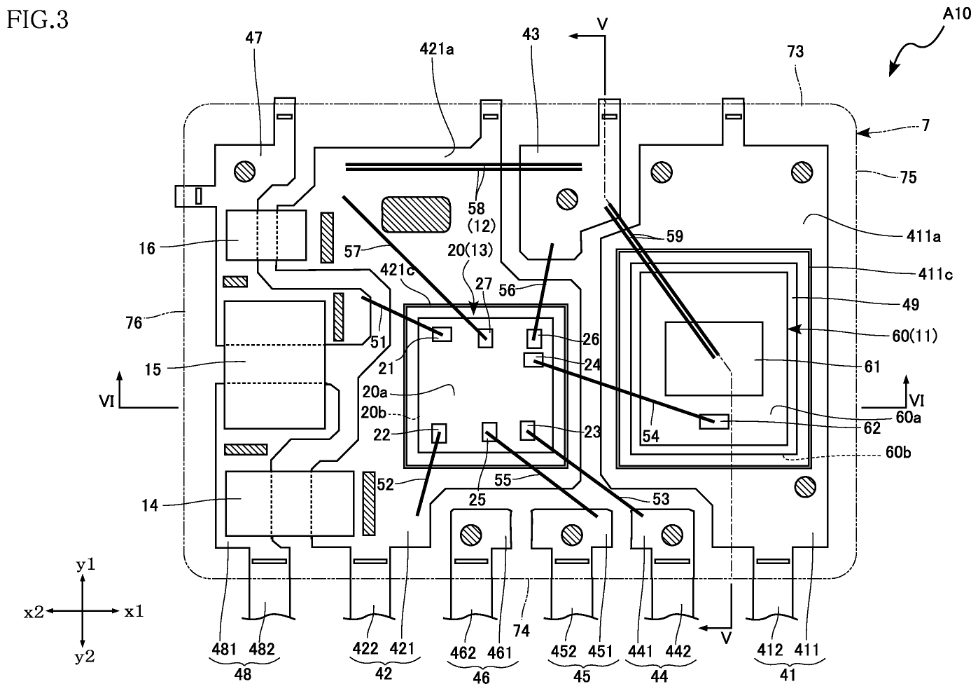

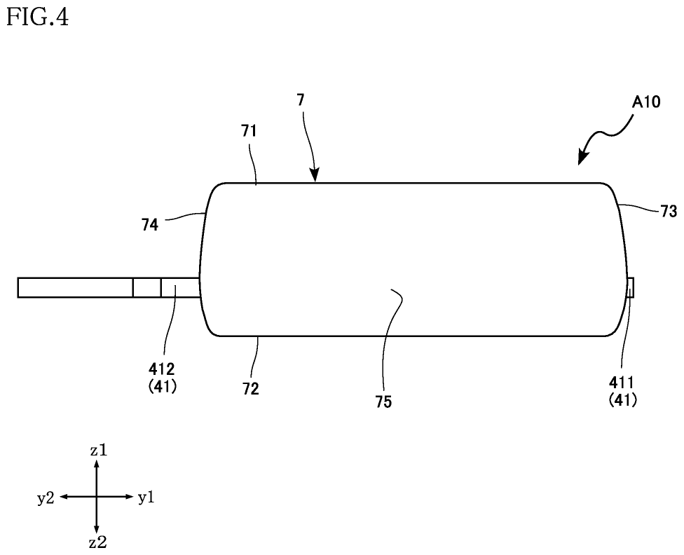

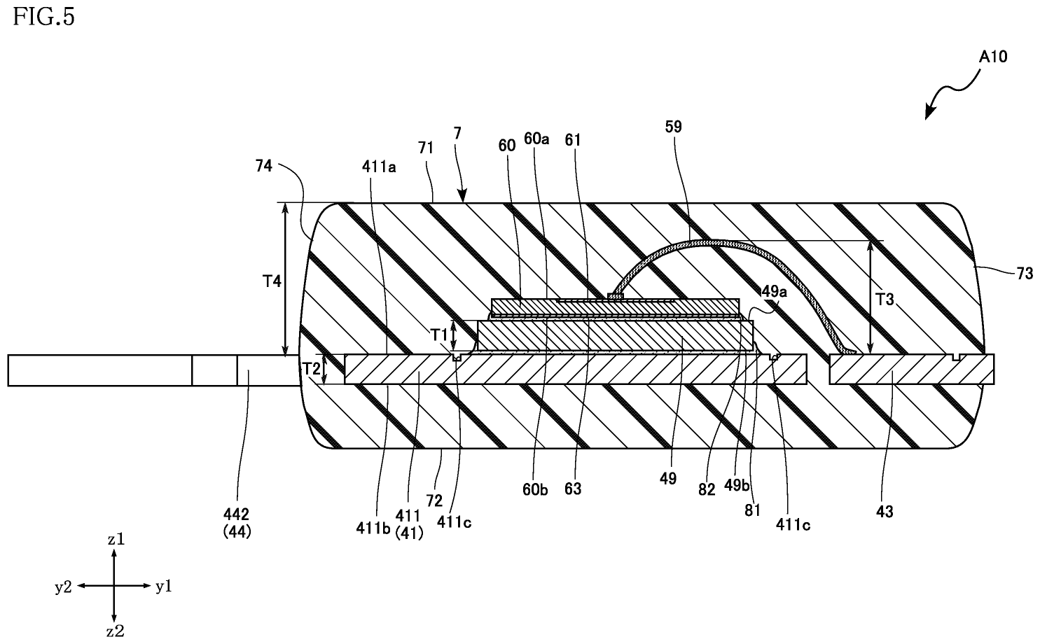

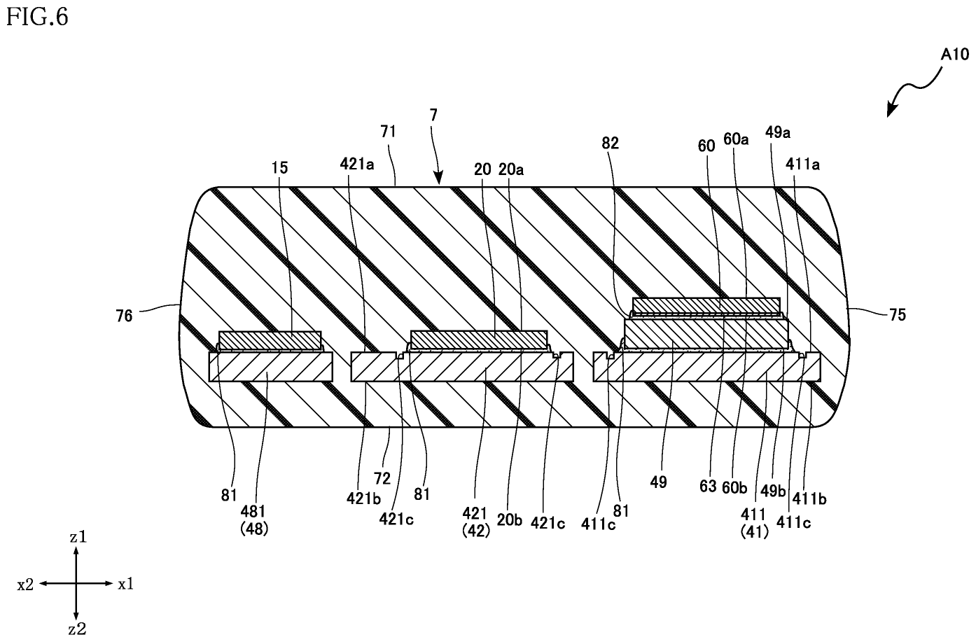

FIG. 2 is a plan view illustrating the semiconductor device A10. FIG. 3 is a plan view illustrating the semiconductor device A10. For convenience of understanding, FIG. 3 shows the sealing resin 7 in phantom, and the outline of the sealing resin 7 is indicated by an imaginary line (two-dot chain line). FIG. 4 is a right-side view illustrating the semiconductor device A10. FIG. 5 is a cross-sectional view taken along line V-V in FIG. 3. FIG. 6 is a cross-sectional view taken along line VI-VI in FIG. 3.

The semiconductor device A10 has a portion covered with the sealing resin 7, and the portion has a rectangular shape (or substantially rectangular shape) as viewed in a thickness direction. For convenience of description, the thickness direction of the semiconductor device A10 is referred to as z direction, a direction (vertical direction in FIG. 2) perpendicular to the z direction and in which below-described terminal portions such as a terminal portion 412 protrude is referred to as y direction, and a direction (horizontal direction in FIG. 2) perpendicular to the z direction and the y direction is referred to as x direction. The dimensions of the semiconductor device A10 are not particularly limited, but in the present embodiment, the semiconductor device A10 may have dimensions of approximately 4 to 5 mm in the z direction, approximately 16 to 17 mm in the x direction, and approximately 11 to 12 mm in the y direction.

Each of the leads 41 to 48 is electrically connected to the switching element 60 or the control element 20, and forms a conductive path between either the switching element 60 or the control element 20 and circuit wiring when the semiconductor device A10 is mounted on a circuit board. The leads 41 to 48 are made of a lead frame formed by punching a metal plate, for example. The leads 41 to 48 are made of metal, preferably Cu or Ni, an alloy thereof, or 42 alloy, for example. Although not particularly limited, each of the leads 41 to 48 may have a thickness of approximately 0.5 mm in the present embodiment.

As shown in FIGS. 3 and 5, the lead 41 supports the switching element 60 and is electrically connected to the switching element 60. The lead 41 includes a mount portion 411 and a terminal portion 412.

The mount portion 411 is mostly covered with the sealing resin 7, and has the switching element 60 mounted thereon. The mount portion 411 is located at the end of the sealing resin 7 on an x1 side in the x direction, and extends over the entirety of the sealing resin 7 in the y direction. The mount portion 411 includes an obverse surface 411a, a reverse surface 411b, and a groove 411c. The obverse surface 411a and the reverse surface 411b face away from each other in the z direction. The obverse surface 411a faces a z1 side in the z direction. The switching element 60 and the metal plate 49 are arranged on the obverse surface 411a. The reverse surface 411b faces a z2 side in the z direction. The groove 411c is recessed from the obverse surface 411a in the z direction, and has a rectangular shape as viewed in the z direction (also referred to as “in plan view”). The metal plate 49 is bonded to the area surrounded by the groove 411c in the obverse surface 411a. In other words, the groove 411c surrounds the metal plate 49 as viewed in the z direction.

The terminal portion 412 is connected to the end of the mount portion 411 on a y2 side in the y direction, and is electrically connected to the switching element 60 via the mount portion 411. The terminal portion 412 extends in the y direction, and protrudes from the sealing resin 7. The terminal portion 412 serves as the output terminal OUT.

As shown in FIG. 3, the lead 42 supports the control element 20 and is electrically connected to the control element 20. The lead 42 includes a mount portion 421 and a terminal portion 422.

The mount portion 421 is mostly covered with the sealing resin 7, and has the control element 20 mounted thereon. The mount portion 421 is offset from the mount portion 411 toward an x2 side in the x direction, and extends over the entirety of the sealing resin 7 in the y direction. The mount portion 421 includes an obverse surface 421a, a reverse surface 421b, and a groove 421c. The obverse surface 421a and the reverse surface 421b face away from each other in the z direction. The obverse surface 421a faces the z1 side in the z direction. The obverse surface 421a has the control element 20 arranged thereon, and has the bonding wire 52 bonded thereto. The reverse surface 421b faces the z2 side in the z direction. The groove 421c is recessed from the obverse surface 421a in the z direction, and has a rectangular shape as viewed in the z direction. The control element 20 is bonded to the area surrounded by the groove 421c in the obverse surface 421a. In other words, the groove 421c surrounds the control element as viewed in the z direction.

The terminal portion 422 is connected to the end of the mount portion 421 on the y2 side in the y direction, and is electrically connected to the control element 20 via the mount portion 421 and the bonding wires 52 and 57. The terminal portion 422 extends in the y direction, and protrudes from the sealing resin 7. The terminal portion 422 serves as the ground terminal GND.

As shown in FIG. 3, the lead 43 is located between the lead 41 and the lead 42 in the x direction, and is located at the end of the sealing resin 7 on a y1 side in the y direction. The bonding wires 56, 58, and 59 are bonded to the lead 43. The lead 43 is mostly covered with the sealing resin 7, and is partially exposed from the sealing resin 7. As shown in FIG. 3, the leads 44 to 46 are located between the lead 41 and the lead 42 in the x direction, and is located at the end of the sealing resin 7 on the y2 side in the y direction. The leads 44 to 46 are aligned in the stated order from the x1 side to the x2 side in the x direction.

The lead 44 includes a pad portion 441 and a terminal portion 442. The pad portion 441 is covered with the sealing resin 7, and has the bonding wire 53 bonded thereto. The terminal portion 442 is connected to the end of the pad portion 441 on the y2 side in the y direction, and is electrically connected to the control element 20 via the pad portion 441 and the bonding wire 53. The terminal portion 442 extends in the y direction, and protrudes from the sealing resin 7. The terminal portion 442 serves as the input terminal IN.

The lead 45 includes a pad portion 451 and a terminal portion 452. The pad portion 451 is covered with the sealing resin 7, and has the bonding wire 55 bonded thereto. The terminal portion 452 is connected to the end of the pad portion 451 on the y2 side in the y direction, and is electrically connected to the control element 20 via the pad portion 451 and the bonding wire 55. The terminal portion 452 extends in the y direction, and protrudes from the sealing resin 7. The terminal portion 452 serves as the feedback terminal FB.

The lead 46 is a so-called dummy terminal. The lead 46 includes a pad portion 461 and a terminal portion 462. The pad portion 461 is covered with the sealing resin 7. The terminal portion 462 is connected to the end of the pad portion 461 on the y2 side in the y direction. The terminal portion 462 extends in the y direction, and protrudes from the sealing resin 7.

As shown in FIG. 3, the lead 47 is offset from the mount portion 421 toward the x2 side in the x direction, and is at the corner of the sealing resin 7 on the y1 side in the y direction and the x2 side in the x direction. The lead 47 is mostly covered with the sealing resin 7, and is partially exposed from the sealing resin 7.

As shown in FIG. 3, the lead 48 includes a mount portion 481 and a terminal portion 482. The mount portion 481 is covered with the sealing resin 7. The mount portion 481 is offset from the mount portion 421 toward the x2 side in the x direction, and is at the corner of the sealing resin 7 on the y2 side in the y direction and the x2 side in the x direction. The terminal portion 482 is connected to the end of the mount portion 481 on the y2 side in the y direction. The terminal portion 482 extends in the y direction, and protrudes from the sealing resin 7. The terminal portion 482 serves as the power supply terminal VDD.

As shown in FIG. 3, the capacitor 16 is bridge-connected between the lead 47 and the mount portion 421. The capacitor 14 is bridge-connected between the mount portion 481 and the mount portion 421. The resistor 15 is bridge-connected between the lead 47 and the mount portion 481. The leads 47 and 48, the capacitors 14 and 16, and the resistor 15 form a high-frequency filter (omitted in FIG. 1), which is a pi (n) low-pass filter, and removes high-frequency noise inputted from the terminal portion 482 (power supply terminal VDD).

Each of the leads 41 to 48 has a through-hole formed therethrough. In FIG. 3, the through-holes are hatched for convenience of understanding. The through-holes are filled with the sealing resin 7, so that the adhesion between the leads 41 to 48 and the sealing resin 7 is enhanced. Each of the leads 41 to 48 has a groove formed in the vicinity of the boundary between the portion covered with the sealing resin 7 and the portion not covered with the sealing resin 7. The grooves suppress the outward flow of a protective resin, such as polyimide, that is applied to protect the bonding points of the leads 41 to 48 where the bonding wires 51 to 59 are bonded, during the process performed before the leads 41 to 48 are covered with the sealing resin 7. As shown in FIG. 2, the terminal portions 412, 442, 452, 462, 422, and 482 have the same shape, and are aligned in the stated order at equal intervals from the x1 side to the x2 side in the x direction. Note that the shape and arrangement of each of the leads 41 to 48 is not limited.

It is possible to provide a plating layer, such as a Ni plating layer, for the area of the obverse surface 411a of the mount portion 411 where the metal plate 49 is bonded, and for the area of the obverse surface 421a of the mount portion 421 where the control element 20 is bonded. A portion of each of the terminal portions 412, 442, 452, 462, 422, and 482, which is exposed from the sealing resin 7, may be formed with a plating layer made of an alloy that mainly contains Sn, for example.

The metal plate 49 is provided between the mount portion 411 of the lead 41 and the switching element 60. The metal plate 49 has a rectangular plate-like shape as viewed in the z direction and is made of a metal having high thermal conductivity. Although not particularly limited, the metal plate 49 is made of Cu in the present embodiment. The metal plate 49 electrically connects the switching element 60 and the lead 41, and transfers the heat generated by the switching element 60 to the lead 41.

As shown in FIG. 3, the metal plate 49 is arranged at the center (or substantially at the center) of the obverse surface 411a of the mount portion 411 of the lead 41 as viewed in the z direction, specifically in the area surrounded by the groove 411c. As shown in FIG. 5, the metal plate 49 has an obverse surface 49a and a reverse surface 49b. The obverse surface 49a and the reverse surface 49b face away from each other in the z direction. The obverse surface 49a faces the z1 side in the z direction. The reverse surface 49b faces the z2 side in the z direction. The reverse surface 49b of the metal plate 49 is bonded to the obverse surface 411a of the mount portion 411 via a bonding member 81. The obverse surface 49a of the metal plate 49 is bonded to the switching element 60 via a bonding member 82. The bonding members 81 and 82 are conductive bonding members, such as solder. Note that the bonding members 81 and 82 may be other conductive bonding members, such as silver paste or sintered silver bonding members. Alternatively, the bonding members 81 and 82 may be bonding members that are different from each other. The obverse surface 49a and the reverse surface 49b of the metal plate 49 may be formed with metal layers, such as Ni metal layers or Au metal layers.

As shown in FIG. 5, in the present embodiment, a first dimension T1 of the metal plate 49 in the z direction is at least 80% and at most 150% of a second dimension T2 of the lead 41 in the z direction. An increase in the first dimension T1 can improve the heat dissipation capability (dynamic heat dissipation capability) of the semiconductor device A10. However, an increase in the first dimension T1 increases a height dimension T3 of the loop of each of the bonding wires 54 and 59 connected to the switching element 60 (the height dimension T3 being the distance between the mount portion 411 and the portion of each bonding wire 54, 59 that is farthest from the mount portion 411 in the z direction). If the dimension T3 is too large, portions of the bonding wires 54 and 59 may be exposed from the sealing resin 7. The first dimension T1 is set such that the dimension T3 is smaller than a thickness dimension T4 of the sealing resin 7 formed on the obverse surface 411a of the mount portion 411 (the dimension T4 being the distance from the obverse surface 411a to a resin obverse surface 71 described below) by at least a predetermined dimension, and that the transient thermal resistance of the switching element 60 is no greater than a predetermined value. In the present embodiment, the first dimension T1 is at least 0.5 mm and at most 0.7 mm. However, the first dimension T1 is not limited to this example.

It is preferable that a first area S1, which is the area of the metal plate 49 as viewed in the z direction, be large. In the present embodiment, the first area S1 is at least 100% and at most 120% of a second area S2, which is the area of the switching element 60 as viewed in the z direction. Furthermore, the first area S1 is at least 30% and at most 80% of a third area S3, which is the area of the lead 41 as viewed in the z direction. Note that the first area S1 is not limited to this example. When the third area S3 is fixed, it is preferable that the second area S2 be large. In the present embodiment, the second area S2 is at least 30% and at most 80% of the third area S3.

The switching element 60 is a semiconductor element that realizes the switching element 11 (see FIG. 1). In the present embodiment, the switching element 60 is an IGBT. The switching element 60 contains a semiconductor material such as silicon (Si), silicon carbide (SiC), or gallium nitride (GaN), and has a rectangular plate-like shape as viewed in the z direction. As shown in FIGS. 3 and 5, the switching element 60 includes an element obverse surface 60a, an element reverse surface 60b, a first electrode 61, a second electrode 62, and a third electrode 63.

The element obverse surface 60a and the element reverse surface 60b face away from each other in the z direction. The element obverse surface 60a faces the z1 side in the z direction. The element reverse surface 60b faces the z2 side in the z direction. The first electrode 61 and the second electrode 62 are arranged on the element obverse surface 60a. The third electrode 63 is arranged on the element reverse surface 60b. In the present embodiment, the first electrode 61 is an emitter electrode, the second electrode 62 is a gate electrode, and the third electrode 63 is a collector electrode.

As shown in FIG. 3, the switching element 60 is provided at the center (or substantially at the center) of the obverse surface 411a of the mount portion 411 of the lead 41 as viewed in the z direction, specifically in the area surrounded by the groove 411c. In the present embodiment, the metal plate 49 is provided between the switching element 60 and the obverse surface 411a. As shown in FIG. 5, the switching element 60 is bonded to the center (or substantially the center) of the obverse surface 49a of the metal plate 49 via the bonding member 82, with the element reverse surface 60b facing the z2 side in the z direction. The switching element 60 and the metal plate 49 overlap with each other as viewed in the z direction. In the present embodiment, the entirety of the switching element 60 is encompassed by the metal plate 49 as viewed in the z direction. The third electrode 63 of the switching element 60 is bonded to the obverse surface 49a of the metal plate 49 via the bonding member 82. The metal plate 49 is bonded to the mount portion 411 of the lead 41 via the bonding member 81. As a result, the third electrode 63 (collector electrode) is electrically connected to the terminal portion 412 (output terminal OUT) of the lead 41 via the metal plate 49.

As shown in FIGS. 3 and 5, the first electrode 61 of the switching element 60 is electrically connected to the lead 43 via the bonding wires 59. As shown in FIG. 3, the lead 43 is electrically connected to the lead 42 via the bonding wires 58. As a result, the first electrode 61 (emitter electrode) of the switching element 60 is electrically connected to the terminal portion 422 (ground terminal GND) of the lead 42. As shown in FIG. 3, the second electrode 62 (gate electrode) of the switching element 60 is electrically connected to the control element 20 (the pad 24 described below) via the bonding wire 54. This allows the gate drive signal to be inputted to the second electrode 62 (gate electrode) from the control element 20 (pad 24).

The control element 20 is a semiconductor element in which the control circuit 13 (see FIG. 1) is integrated. The control element 20 contains a semiconductor material, and has a rectangular plate-like shape as viewed in the z direction. As shown in FIG. 3, the control element 20 includes an element obverse surface 20a, an element reverse surface 20b, the power supply pad 21, the ground pad 22, the input pad 23, the gate output pad 24, the feedback output pad 25, the sense input pad 26, and the sense ground pad 27 (hereinafter, may be abbreviated as “pads 21 to 27”).

The element obverse surface 20a and the element reverse surface 20b face away from each other in the z direction. The element obverse surface 20a faces the z1 side in the z direction. The element reverse surface 20b faces the z2 side in the z direction. The pads 21 to 27 are arranged on the element obverse surface 60a.

As shown in FIG. 3, the control element 20 is provided in the area that is located within the obverse surface 421a of the mount portion 421 of the lead 42, and that is surrounded by the groove 421c as viewed in the z direction. The control element 20 is bonded to the obverse surface 421a of the mount portion 421 via the bonding member 81, with the element reverse surface 20b facing the z2 side in the z direction. Note that a bonding member different from the bonding member 81 may be used to bond the control element 20 to the obverse surface 421a of the mount portion 421. The bonding member may be insulative.

The power supply pad 21 is electrically connected to the lead 47 via the bonding wire 51. The ground pad 22 is electrically connected to the lead 42 (ground terminal GND) via the bonding wire 52. The input pad 23 is electrically connected to the lead 44 (input terminal IN) via the bonding wire 53. The gate output pad 24 is electrically connected to the second electrode 62 (gate electrode) of the switching element 60 via the bonding wire 54. The feedback output pad is electrically connected to the lead 45 (feedback terminal FB) via the bonding wire 55. The sense input pad 26 is electrically connected to the lead 43 via the bonding wire 56. The sense ground pad 27 is electrically connected to the lead 42 via the bonding wire 57.

Each of the bonding wires 51 to 59 electrically connects two elements that are spaced apart from each other. The bonding wires 51 to 59 are made of Al, for example. Note that the bonding wires 51 to 59 may be made of another metal such as Au or Cu, or may be made of an alloy containing any of these metals. The bonding wire 51 is bonded to the pad 21 of the control element 20 and the lead 47. The bonding wire 52 is bonded to the pad 22 of the control element 20 and the mount portion 421 of the lead 42. The bonding wire 53 is bonded to the pad 23 of the control element 20 and the pad portion 441 of the lead 44. The bonding wire 54 is bonded to the pad 24 of the control element 20 and the second electrode 62 of the switching element 60. The bonding wire 55 is bonded to the pad 25 of the control element 20 and the pad portion 451 of the lead 45. The bonding wire 56 is bonded to the pad 26 of the control element 20 and the lead 43. The bonding wire 57 is bonded to the pad 27 of the control element 20 and the mount portion 421 of the lead 42. The bonding wires 58 are bonded to the mount portion 421 of the lead 42 and the lead 43. In the present embodiment, two bonding wires 58 are provided. The bonding wires 59 are bonded to the first electrode 61 of the switching element 60 and the lead 43. In the present embodiment, two bonding wires 59 are provided. Note that the constituent material, thickness, and number of the bonding wires 51 to 59 are not particularly limited. The semiconductor device A10 may include another connecting member, such as a metal plate or a metal ribbon, instead of any of the bonding wires 51 to 59.

In the present embodiment, the first electrode 61 of the switching element 60 is not directly connected to the lead 42 (ground terminal GND) by bonding wires, but is connected to the lead 43 by the bonding wires 59. The lead 43 is connected to the lead 42 (ground terminal GND) by the bonding wires 58, and is connected to the sense input pad 26 by the bonding wire 56. Accordingly, the resistance component of the bonding wires 58 serves as the current sensing resistor 12.

The sealing resin 7 is a semiconductor sealing material that is electrically insulative. The sealing resin 7 covers the entirety of each of the switching element 60, the control element 20, the capacitors 14 and 16, the resistor 15, the metal plate 49, and the bonding wires 51 to 59, and also covers a portion of each of the leads 41 to 48. The sealing resin 7 is made of a black epoxy resin, for example. Note that the constituent material and color of the sealing resin 7 are not particularly limited. The sealing resin 7 is formed by transfer molding with a mold, for example. Note that the method for forming the sealing resin 7 is not particularly limited. As shown in FIGS. 2 to 5, the sealing resin 7 has a resin obverse surface 71, a resin reverse surface 72, and a plurality of resin side surfaces 73 to 76.

The resin obverse surface 71 and the resin reverse surface 72 face away from each other in the z direction. The resin obverse surface 71 faces the z1 side in the z direction, and the resin reverse surface 72 faces the z2 side in the z direction. Each of the resin side surfaces 73 to 76 is connected to and flanked by the resin obverse surface 71 and the resin reverse surface 72. As shown in FIG. 2, the two resin side surfaces 73 and 74 face away from each other in the y direction. The resin side surface 73 is offset toward the y1 side in the y direction, and faces the y1 side in the y direction. The resin side surface 74 is offset toward the y2 side in the y direction, and faces the y2 side in the y direction. The two resin side surfaces 75 and 76 face away from each other in the x direction. The resin side surface 75 is offset toward the x1 side in the x direction, and faces the x1 side in the x direction. The resin side surface 76 is offset toward the x2 side in the x direction, and faces the x2 side in the x direction.

The resin side surfaces 73 to 76 include respective inclined surface portions connected to the resin obverse surface 71 and inclined to become closer to each other as proceeding to the resin obverse surface 71. In other words, the sealing resin 7 includes a part surrounded by the inclined surface portions connected to the resin obverse surface 71, and this part has a tapered shape whose cross-sectional area contained in the xy plane decreases toward the resin obverse surface 71. Likewise, the resin side surfaces 73 to 76 include respective inclined surface portions connected to the resin reverse surface 72 and inclined to become closer to each other as proceeding to the resin reverse surface 72. In other words, the sealing resin 7 includes a part surrounded by the inclined surface portions connected to the resin reverse surface 72, and this part has a tapered shape whose cross-sectional area contained in the xy plane decreases toward the resin reverse surface 72.

The terminal portions 412, 442, 452, 462, 422, and 482 protrude from the resin side surface 74. A portion of each of the leads 41, 42, 43, and 47 is exposed from the resin side surface 73, and a portion of the lead 47 is exposed from the resin side surface 76. These exposed portions are formed by cutting a lead frame. The shape of the sealing resin 7 shown in FIGS. 2 to 5 is merely an example. The shape of the sealing resin 7 is not limited to this example.

The layout of the internal components of the semiconductor device A10 is not limited to the one shown in FIG. 3. The package type of the semiconductor device A10 is not limited to the SIP, and may be a dual in-line package (DiP) or a zigzag in-line package (ZIP). Alternatively, the semiconductor device A10 may be a surface mount package.

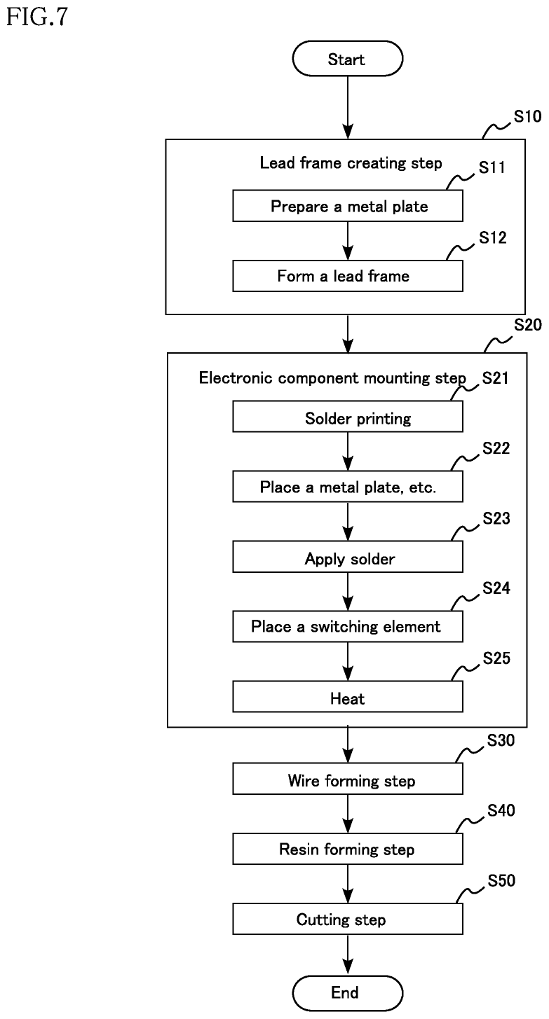

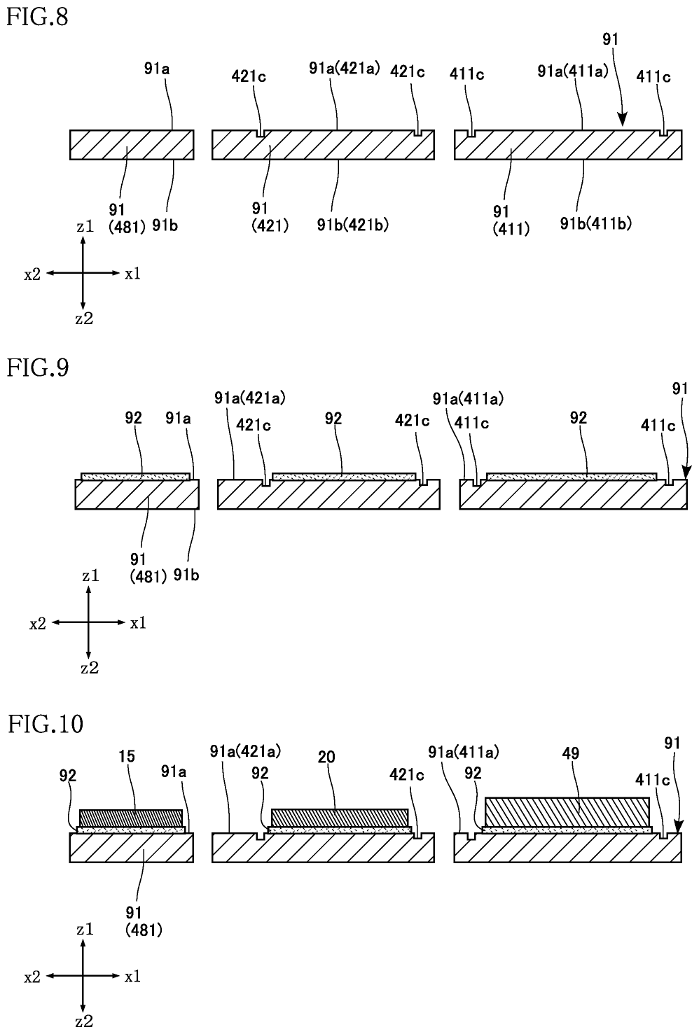

The following describes an example of a method for manufacturing the semiconductor device A10 with reference to FIGS. 7 to 13. Note that the manufacturing method described below is merely an example for realizing the semiconductor device A10, and the manufacturing method of the present disclosure is not limited to this. FIG. 7 is a flowchart showing an example of the method for manufacturing the semiconductor device A10. FIGS. 8 to 13 each show a step in the example of the method for manufacturing the semiconductor device A10. FIGS. 8 to 13 are cross-sectional views corresponding to FIG. 6. Note that the x direction, the y direction, and the z direction shown in FIGS. 8 to 13 correspond to those shown in FIGS. 1 to 6.

As shown in FIG. 7, the method for manufacturing the semiconductor device A10 includes a lead frame creating step (S10), an electronic component mounting step (S20), a wire forming step (S30), a resin forming step (S40), and a cutting step (S50).

The lead frame creating step (S10) is a step of creating a lead frame 91 that will be formed into the leads 41 to 48. In the lead frame creating step, a metal plate, from which the lead frame 91 is made, is prepared first (S11). Then, as shown in FIG. 8, the metal plate undergoes a process such as stamping or etching to form the lead frame 91 (S12). The lead frame 91 includes portions that will be formed into the leads 41 to 48, and a non-illustrated frame that is connected to the leads 41 to 48. The lead frame 91 has an obverse surface 91a and a reverse surface 91b that face away from each other in the z direction. The obverse surface 91a faces the z1 side in the z direction, and includes a portion that will be formed into the obverse surface 411a of the mount portion 411 and a portion that will be formed into the obverse surface 421a of the mount portion 421. The reverse surface 91b faces the z2 side in the z direction, and includes a portion that will be formed into the reverse surface 411b of the mount portion 411 and a portion that will be formed into the reverse surface 421b of the mount portion 421. The portion of the lead frame 91 that will be formed into the mount portion 411 has the groove 411c recessed from the obverse surface 91a in the z direction. The portion of the lead frame 91 that will be formed into the mount portion 421 has the groove 421c recessed from the obverse surface 91a in the z direction. The groove 411c and the groove 421c are formed by stamping or half-etching. Note that the shape and formation method of the lead frame 91 are not particularly limited.

The electronic component mounting step (S20) is a step of mounting the switching element 60, the control element 20, the capacitors 14 and 16, the resistor 15, and the metal plate 49 on the obverse surface 91a of the lead frame 91. This step begins with applying solder paste 92 on the obverse surface 91a of the lead frame 91 by, for example, screen printing. Note that the solder paste 92 may be applied by a method other than screen printing. The solder paste 92 is applied to the area surrounded by the groove 411c in the portion that will be formed into the obverse surface 411a, to the area surrounded by the groove 421c in the portion that will be formed into the obverse surface 421a, and to a predetermined area. The solder paste 92 is also applied to a predetermined area in the portion that will be formed into the lead 47, and to a predetermined area in the portion that will be formed into the lead 48 (mount portion 481). It is possible to apply a conductive bonding member other than the solder paste 92.

Next, as shown in FIG. 10, components are placed on the solder paste 92. The metal plate 49 is placed on the solder paste 92 applied to the area surrounded by the groove 411c in the portion that will be formed into the obverse surface 411a. The control element 20 is placed on the solder paste 92 applied to the area surrounded by the groove 421c in the portion that will be formed into the obverse surface 421a. The resistor 15 is placed across the solder paste 92 applied to the predetermined area of the portion that will be formed into the mount portion 481 and the solder paste 92 applied to the predetermined area of the portion that will be formed into the lead 47. Although not illustrated, the capacitor 14 is placed across the solder paste 92 applied to the predetermined area of the portion that will be formed into the mount portion 481 and the solder paste 92 applied to the predetermined area of the portion that will be formed into the obverse surface 421a. The capacitor 16 is placed across the solder paste 92 applied to the predetermined area of the portion that will be formed into the lead 47 and the solder paste 92 applied to the predetermined area of the portion that will be formed into the obverse surface 421a.

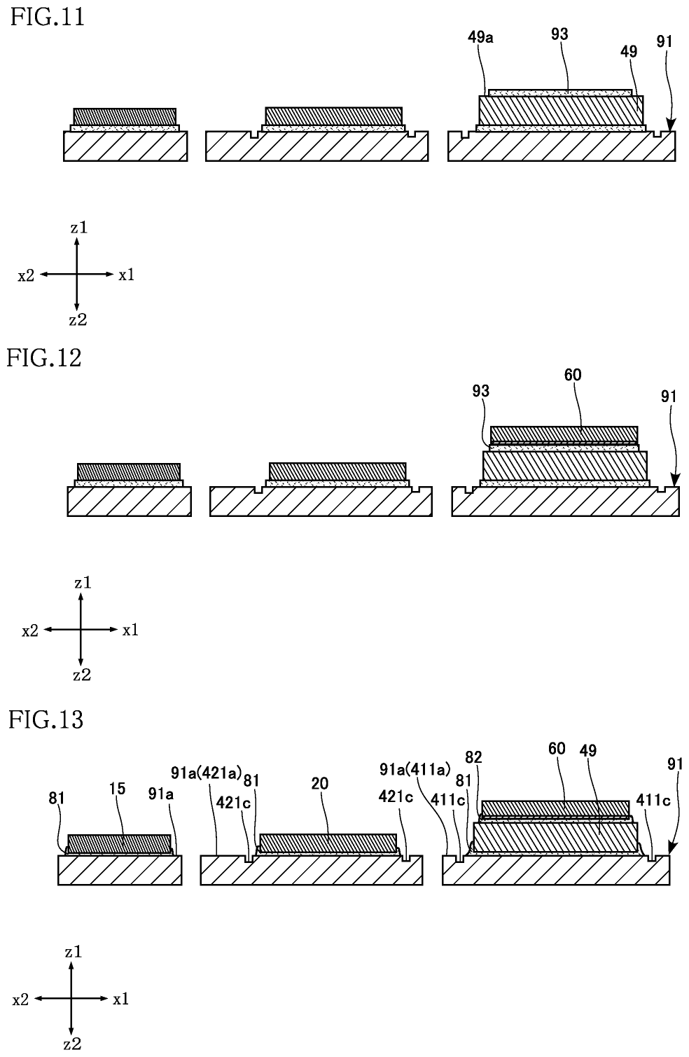

Next, as shown in FIG. 11, solder paste 93 is applied to the obverse surface 49a of the metal plate 49 with, for example, a dispenser. The solder paste 93 may be applied by a method other than the method using a dispenser. It is possible to apply a conductive bonding member other than the solder paste 93. Next, as shown in FIG. 12, the switching element 60 is placed on the solder paste 93.

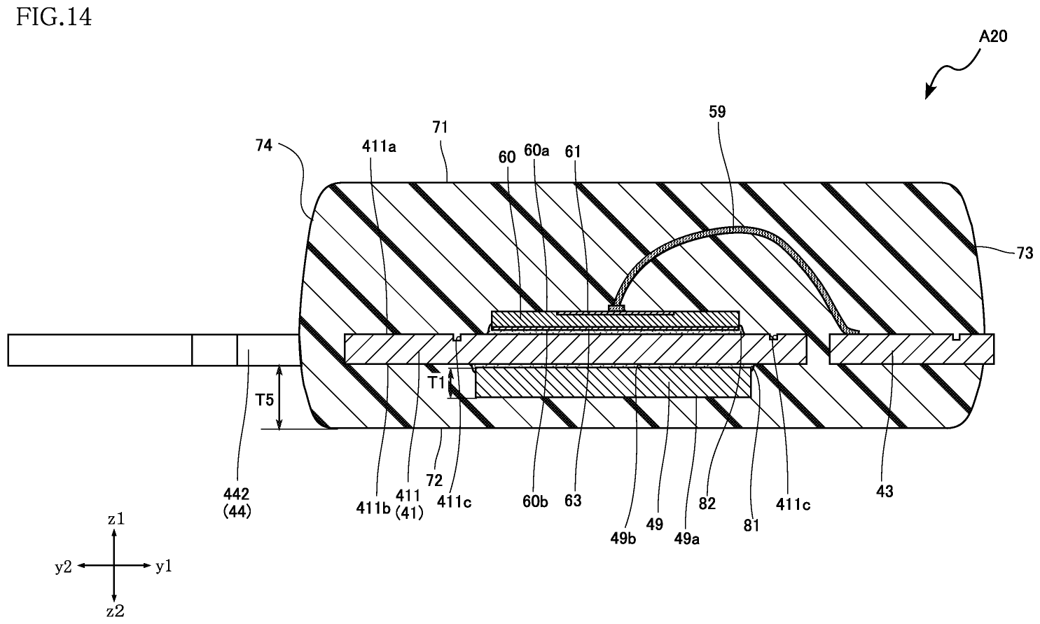

Then, the solder pastes 92 and 93 are heated and melted by, for example, reflowing. At this point, the groove 411c and the groove 421c prevent the melted solder paste 92 from spreading too much on the obverse surface 91a. After that, the melted solder pastes 92 and 93 are cooled and solidified. As a result, the solder paste 92 turns into the bonding member 81, and the solder paste 93 turns into the bonding member 82, as shown in FIG. 13. The metal plate 49, the control element 20, the resistor 15, and the capacitors 14 and 16 are bonded to the obverse surface 91a of the lead frame 91 via the bonding member 81. The switching element 60 is bonded to the metal plate 49 via the bonding member 82. The method for mounting the components in the electronic component mounting step (S20) is not particularly limited.

The wire forming step (S30) is a step of forming the bonding wires 51 to 59. In this step, the bonding wires 51-53 and 55-57 are bonded to the pads 21-23 and 25-27 of the control element 20, respectively, and to the obverse surface 91a of the lead frame 91. The bonding wire 54 is bonded to the pad 24 of the control element 20 and the second electrode 62 of the switching element 60. The bonding wires 59 are bonded to the first electrode 61 of the switching element 60 and the portion of the lead frame 91 that will be formed into the lead 43. The bonding wires 58 are bonded to the portion of the lead frame 91 that will be formed into the lead 43 and the portion of the lead frame 91 that will be formed into the lead 42. In the wire forming step (S30), the order of forming the bonding wires 51 to 59 is not particularly limited, and the method for forming the bonding wires 51 to 59 is also not particularly limited.

The resin forming step (S40) is a step of forming the sealing resin 7. The step is performed by well-known transfer molding using a mold, for example. Specifically, a portion of the lead frame 91, the switching element 60, the control element 20, the capacitors 14 and 16, the resistor 15, the metal plate 49, and the bonding wires 51 to 59 are surrounded by a mold. Next, a liquid resin material is injected into the space defined by the mold. Next, the resin material is cured. This forms the sealing resin 7. Note that the method for forming the sealing resin 7 in the resin forming step (S40) is not particularly limited.

The cutting step (S50) is a step of cutting the lead frame 91. In this step, the lead frame 91 is cut appropriately at portions exposed from the sealing resin 7. As a result, the leads 41 to 48 are separated from each other. Note that the cutting method in the cutting step (S50) is not particularly limited. The semiconductor device A10 is manufactured through the steps described above.

The following describes advantages of the semiconductor device A10.

According to the present embodiment, the semiconductor device A10 includes the metal plate 49 provided between the mount portion 411 of the lead 41 and the switching element 60. This increases the thermal capacity of the semiconductor device A10 as compared to the configuration without the metal plate 49. As a result, the heat dissipation capability (dynamic heat dissipation capability) of the semiconductor device A10 is improved. Since the metal plate 49 is simply bonded to the lead 41, the size of the lead 41 does not change as viewed in the z direction. Furthermore, the first dimension T1 of the metal plate 49 is set such that the dimension T3 is smaller than the dimension T4 by at least a predetermined dimension. As such, the dimension of the sealing resin 7 in the z direction does not change. This allows the semiconductor device A10 to have the same external dimensions as the one without the metal plate 49.

According to the present embodiment, the mount portion 411 includes the groove 411c. The groove 411c prevents the melted solder paste 92 from spreading too much on the obverse surface 411a in the electronic component mounting step (S20). This prevents excessive displacement of the metal plate 49 arranged on the obverse surface 411a. Furthermore, the mount portion 421 includes the groove 421c. The groove 421c prevents the melted solder paste 92 from spreading too much on the obverse surface 421a in the electronic component mounting step (S20). This prevents excessive displacement of the control element 20 arranged on the obverse surface 421a.

According to the present embodiment, bonding the metal plate 49 and so on to the lead frame 91 and bonding the switching element 60 to the metal plate 49 are performed collectively. This simplifies the manufacturing process.

According to the present embodiment, the solder paste 92 is applied to the obverse surface 91a of the lead frame 91 by screen printing. This shortens the time required to perform the step of applying the solder paste 92. Screen printing facilitates the application of the solder paste 92 to the obverse surface 91a because the obverse surface 91a has no steps. The solder paste 93 is applied to the obverse surface 49a of the metal plate 49 with a dispenser. The portion (the obverse surface 49a of the metal plate 49) to which the solder paste 93 is applied has a step relative to the surroundings (the obverse surface 91a of the lead frame 91), and has a small area. Accordingly, it is suitable to use a dispenser for the application.

Although the present embodiment has given an example in which bonding the metal plate 49 and so on to the lead frame 91 and bonding the switching element 60 to the metal plate 49 are performed collectively, the present disclosure is not limited to this example. For example, the metal plate 49 and so on may be bonded to the lead frame 91 first, and then the switching element 60 may be bonded to the metal plate 49. Alternatively, the switching element 60 may be bonded to the metal plate 49 first, and then the metal plate 49 having the switching element 60 bonded thereto, as well as other components, may be bonded to the lead frame 91.

FIGS. 14 to 19 illustrate other embodiments of the present disclosure. In these figures, elements that are the same as or similar to the elements in the above embodiment are provided with the same reference numerals, and descriptions thereof are omitted.

### Second Embodiment

FIG. 14 illustrates a semiconductor device A20 according to a second embodiment of the present disclosure. FIG. 14 is a cross-sectional view illustrating the semiconductor device A20, and corresponds to FIG. 5. The semiconductor device A20 according to the present embodiment is different from the semiconductor device A10 according to the first embodiment in the arrangement position of the metal plate 49. The configurations and operations of the other components in the present embodiment are the same as in the first embodiment. It should be understood that the second embodiment may include any of the components described in the first embodiment in any combination.

The metal plate 49 according to the present embodiment is arranged on the reverse surface 411b, rather than on the obverse surface 411a of the mount portion 411. The switching element 60 according to the present embodiment is bonded to the area surrounded by the groove 411c in the obverse surface 411a of the mount portion 411 via the bonding member 82. The metal plate 49 is bonded to the reverse surface 411b of the mount portion 411 via the bonding member 81. The switching element 60 and the metal plate 49 overlap with each other as viewed in the z direction. In the present embodiment, the entirety of the switching element 60 is encompassed by the metal plate 49 as viewed in the z direction. Although the switching element 60 and the metal plate 49 do not necessarily have to overlap with each other as viewed in the z direction, it is desirable that they overlap with the largest possible overlapping area, and is more desirable that the entirety of the switching element 60 is encompassed by the metal plate 49 as viewed in the z direction. In the present embodiment, the first dimension T1 is set such that the first dimension T1 is smaller than a thickness dimension 15 of the sealing resin 7 formed on the reverse surface 411b of the mount portion 411 (the dimension 15 being the distance from the reverse surface 411b to the resin reverse surface 72) by at least a predetermined dimension, and that the transient thermal resistance of the switching element 60 is no greater than a predetermined value. In the present embodiment, the first dimension T1 is at least 0.5 mm and at most 0.7 mm. However, the first dimension T1 is not limited to this example.

According to the present embodiment, the semiconductor device A20 includes the metal plate 49 bonded to the reverse surface 411b of the mount portion 411 of the lead 41. This increases the thermal capacity of the semiconductor device A20 as compared to the configuration without the metal plate 49. As a result, the heat dissipation capability (dynamic heat dissipation capability) of the semiconductor device A20 is improved. Since the metal plate 49 is simply bonded to the lead 41, the size of the lead 41 does not change as viewed in the z direction. Furthermore, the first dimension T1 of the metal plate 49 is set to be smaller than the dimension T5 by at least a predetermined dimension. As such, the dimension of the sealing resin 7 in the z direction does not change. This allows the semiconductor device A20 to have the same external dimensions as the one without the metal plate 49. Furthermore, the semiconductor device A20 has advantages similar to the semiconductor device A10 owing to its common configuration with the semiconductor device A10. Furthermore, the present embodiment has a higher degree of freedom than the first embodiment in positioning of the metal plate 49 in the x direction and the y direction.

### Third Embodiment

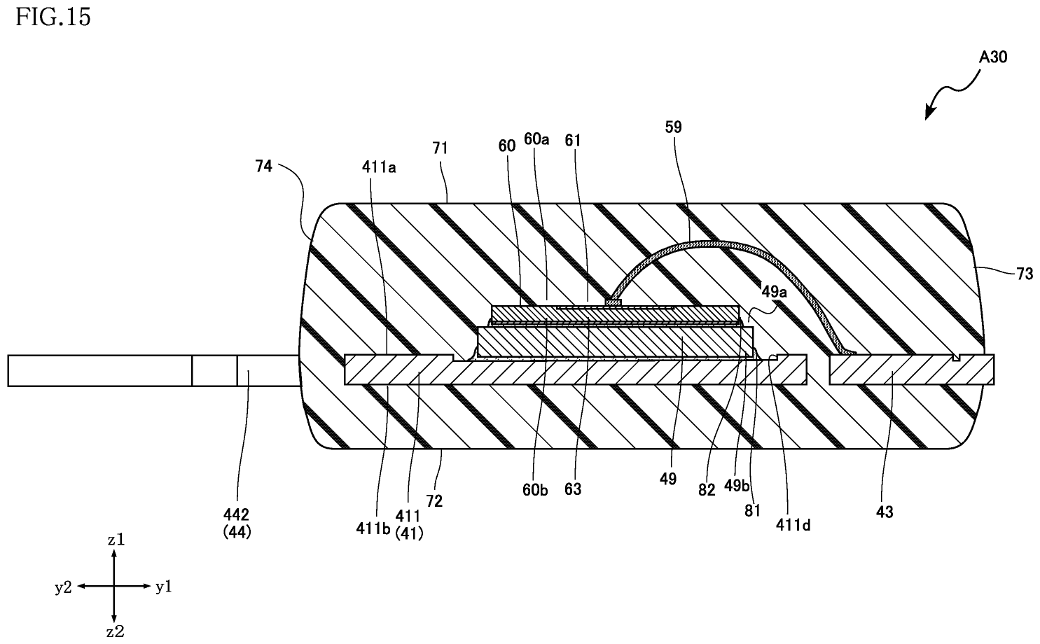

FIG. 15 illustrates a semiconductor device A30 according to a third embodiment of the present disclosure. FIG. 15 is a cross-sectional view illustrating the semiconductor device A30, and corresponds to FIG. 5. The semiconductor device A30 according to the present embodiment is different from the semiconductor device A10 according to the first embodiment in that the mount portion 411 includes a recess instead of the groove 411c. The configurations and operations of the other components in the present embodiment are the same as in the first embodiment. It should be understood that the third embodiment may include any of the components described in the first and second embodiments in any combination.

The mount portion 411 according to the present embodiment does not include the groove 411c. Instead, the mount portion 411 includes a recess 411d. The recess 411d is recessed from the obverse surface 411a in the z direction, and is formed to have a rectangular shape as viewed in the z direction. The recess 411d is formed by recessing the area of the obverse surface 411a surrounded by the groove 411c in the first embodiment to the depth of the groove 411c. The metal plate 49 is bonded to the bottom surface of the recess 411d, rather than on the obverse surface 411a. Although not illustrated, the mount portion 421 also includes a recess instead of the groove 421c, and the control element 20 is bonded to the bottom surface of the recess.

The semiconductor device A30 in the present embodiment also includes the metal plate 49 provided between the mount portion 411 of the lead 41 and the switching element 60, thus having an improved heat dissipation capability (dynamic heat dissipation capability) as compared to the configuration without the metal plate 49. Furthermore, the semiconductor device A30 can have the same external dimensions as the one without the metal plate 49.

According to the present embodiment, the mount portion 411 includes the recess 411d instead of the groove 411c. The recess 411d can also prevent the melted solder paste 92 from spreading too much, which makes it possible to prevent excessive displacement of the metal plate 49. Furthermore, the mount portion 421 includes a recess instead of the groove 421c. The recess can also prevent the melted solder paste 92 from spreading too much, which makes it possible to prevent excessive displacement of the control element 20. Furthermore, the semiconductor device A30 has advantages similar to the semiconductor device A10 owing to its common configuration with the semiconductor device A10.

### Fourth Embodiment

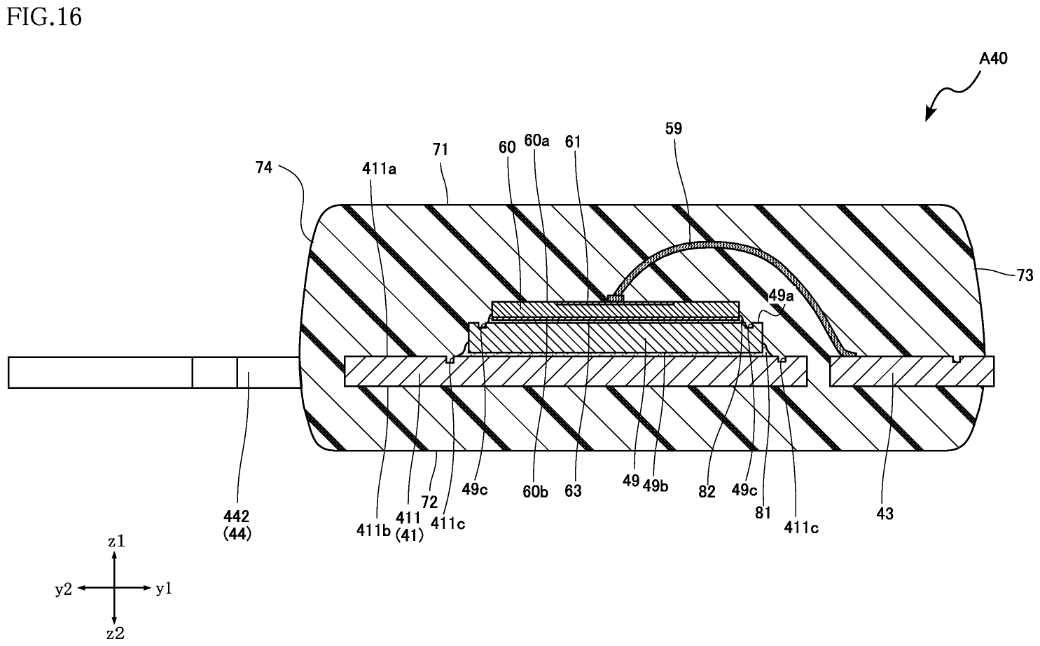

FIG. 16 illustrates a semiconductor device A40 according to a fourth embodiment of the present disclosure. FIG. 16 is a cross-sectional view illustrating the semiconductor device A40, and corresponds to FIG. 5. The semiconductor device A40 according to the present embodiment is different from the semiconductor device A10 according to the first embodiment in that the metal plate 49 includes a groove. The configurations and operations of the other components in the present embodiment are the same as in the first embodiment. It should be understood that the fourth embodiment may include any of the components described in the first to third embodiments in any combination.

The metal plate 49 according to the present embodiment includes a groove 49c. The groove 49c is recessed from the obverse surface 49a in the z direction, and has a rectangular shape as viewed in the z direction. The switching element 60 is bonded to the area surrounded by the groove 49c in the obverse surface 49a. In other words, the groove 49c surrounds the switching element 60 as viewed in the z direction.

The semiconductor device A40 in the present embodiment also includes the metal plate 49 provided between the mount portion 411 of the lead 41 and the switching element 60, thus having an improved heat dissipation capability (dynamic heat dissipation capability) as compared to the configuration without the metal plate 49. Furthermore, the semiconductor device A40 can have the same external dimensions as the one without the metal plate 49. Furthermore, the semiconductor device A40 has advantages similar to the semiconductor device A10 owing to its common configuration with the semiconductor device A10. Furthermore, the metal plate 49 of the semiconductor device A40 includes the groove 49c. The groove 49c prevents the melted solder paste 93 from spreading too much on the obverse surface 49a in the electronic component mounting step (S20). This prevents excessive displacement of the switching element 60 arranged on the obverse surface 49a.

### Fifth Embodiment

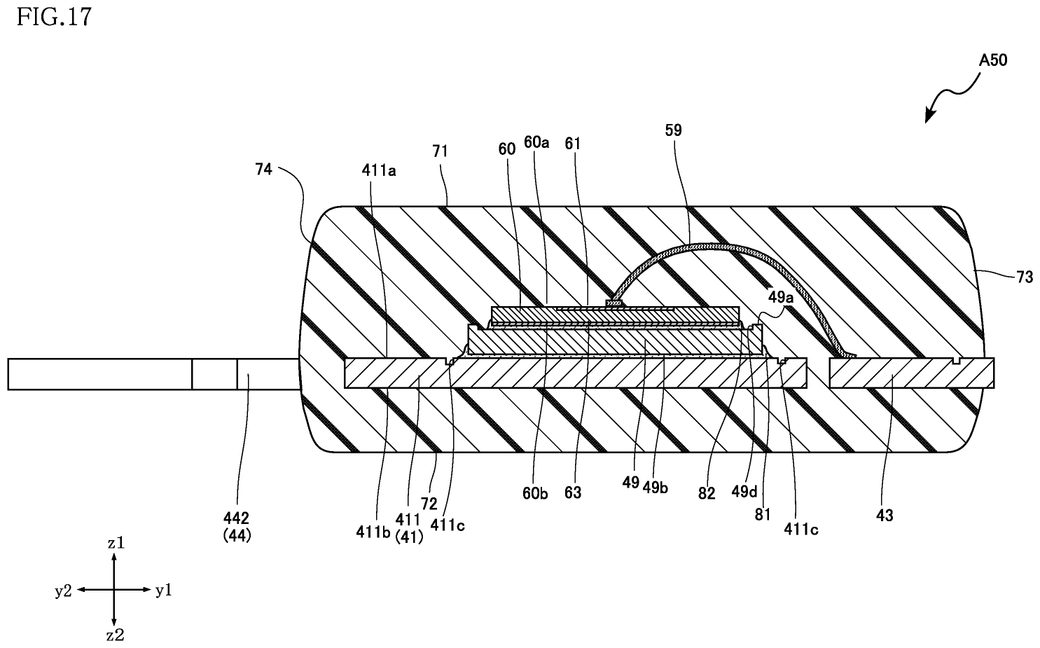

FIG. 17 illustrates a semiconductor device A50 according to a fifth embodiment of the present disclosure. FIG. 17 is a cross-sectional view illustrating the semiconductor device A50, and corresponds to FIG. 5. The semiconductor device A50 according to the present embodiment is different from the semiconductor device A10 according to the first embodiment in that the metal plate 49 includes a recess. The configurations and operations of the other components in the present embodiment are the same as in the first embodiment. It should be understood that the fifth embodiment may include any of the components described in the first to fourth embodiments in any combination.

The metal plate 49 according to the present embodiment includes a recess 49d. The recess 49d is recessed from the obverse surface 49a in the z direction, and is formed to have a rectangular shape as viewed in the z direction. The switching element 60 is bonded to the bottom surface of the recess 49d.

The semiconductor device A50 in the present embodiment also includes the metal plate 49 provided between the mount portion 411 of the lead 41 and the switching element 60, thus having an improved heat dissipation capability (dynamic heat dissipation capability) as compared to the configuration without the metal plate 49. Furthermore, the semiconductor device A50 can have the same external dimensions as the one without the metal plate 49. Furthermore, the semiconductor device A50 has advantages similar to the semiconductor device A10 owing to its common configuration with the semiconductor device A10. Furthermore, the metal plate 49 of the semiconductor device A50 includes the groove 49d. The recess 49d prevents the melted solder paste 93 from spreading too much. This prevents excessive displacement of the switching element 60 arranged on the metal plate 49.

### Sixth Embodiment

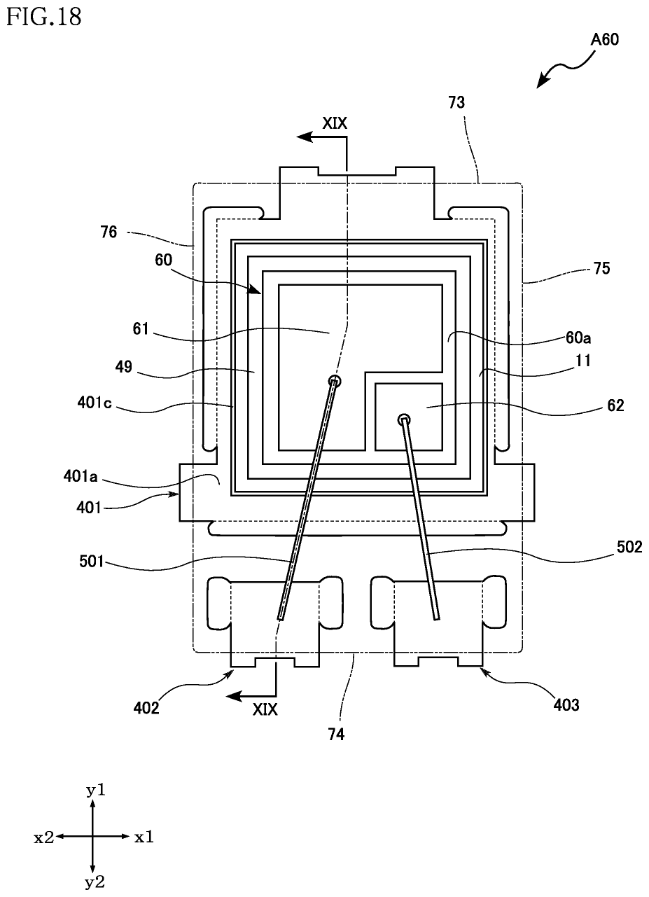

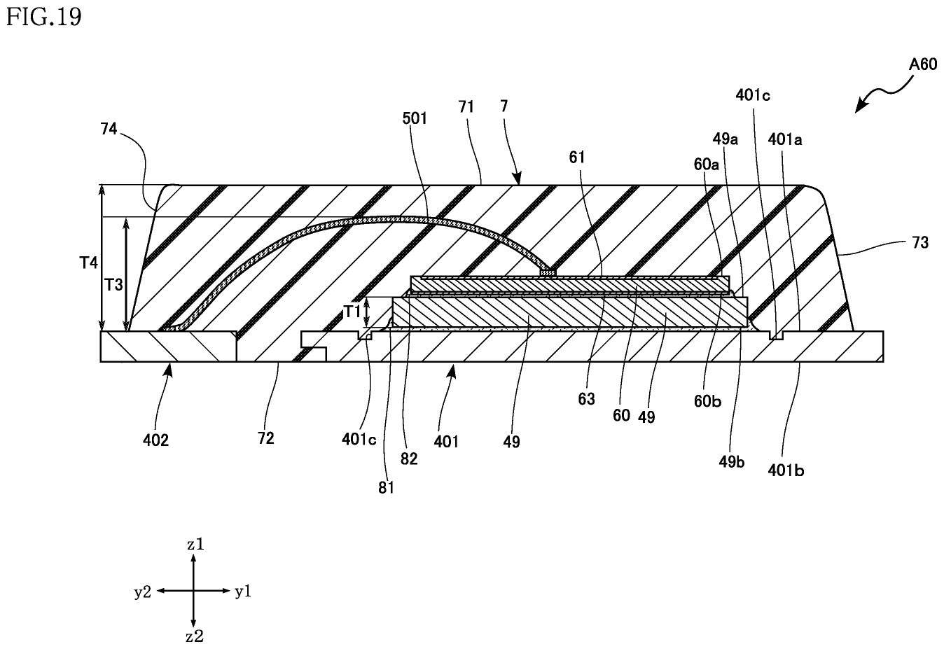

FIGS. 18 and 19 illustrate a semiconductor device A60 according to a sixth embodiment of the present disclosure. FIG. 18 is a plan view illustrating the semiconductor device A60, and corresponds to FIG. 3. For convenience of understanding, FIG. 18 shows the sealing resin 7 in phantom, and the outline of the sealing resin 7 is indicated by an imaginary line (two-dot chain line). FIG. 19 is a cross-sectional view taken along line XIX-XIX in FIG. 18. The semiconductor device A60 according to the present embodiment is different from the semiconductor device A10 according to the first embodiment in being packaged without the control element 20 and passive components. The configurations and operations of the other components in the present embodiment are the same as in the first embodiment. It should be understood that the sixth embodiment may include any of the components described in the first to fifth embodiments in any combination.

The semiconductor device A60 is not an igniter, and is a package having only the switching element 60 therein. The semiconductor device A60 is in a dual flatpack no-leaded (DFN) package. The semiconductor device A60 includes the switching element 60, leads 401 to 403, the metal plate 49, bonding wires 501 and 502, and the sealing resin 7. The switching element 60, the metal plate 49, and the sealing resin 7 are the same as those in the first embodiment.

The leads 401 to 403 are similar to the leads 41 to 48, electrically connected to the switching element 60, and form the conductive paths between the switching element 60 and circuit wiring. The lead 401 includes an obverse surface 401a, a reverse surface 401b, and a groove 401c. The obverse surface 401a and the reverse surface 401b face away from each other in the z direction. The obverse surface 401a faces the z1 side in the z direction. The switching element 60 and the metal plate 49 are arranged on the obverse surface 401a. The reverse surface 401b faces the z2 side in the z direction. The reverse surface 401b is exposed from the sealing resin 7, and serves as a reverse-surface terminal. The groove 401c is recessed from the obverse surface 401a in the z direction, and has a rectangular shape as viewed in the z direction. The metal plate 49 is bonded to the area surrounded by the groove 401c in the obverse surface 401a. In other words, the groove 401c surrounds the metal plate 49 as viewed in the z direction.

The switching element 60 is bonded to the center (or substantially the center) of the obverse surface 49a of the metal plate 49 via the bonding member 82, with the element reverse surface 60b facing the z2 side in the z direction. The switching element 60 and the metal plate 49 overlap with each other as viewed in the z direction. In the present embodiment, the entirety of the switching element 60 is encompassed by the metal plate 49 as viewed in the z direction. The third electrode 63 of the switching element 60 is bonded to the obverse surface 49a of the metal plate 49 via the bonding member 82. The metal plate 49 is bonded to the lead 401 via the bonding member 81. As a result, the lead 401 is electrically connected to the third electrode 63 (collector electrode) of the switching element 60, and serves as a collector terminal.

The bonding wires 501 and 502 are similar to the bonding wires 51 to 59, and each of the bonding wires 501 and 502 electrically connects two elements that are spaced apart from each other. The bonding wire 501 is bonded to the first electrode 61 of the switching element 60 and the lead 402. As a result, the lead 402 is electrically connected to the first electrode 61 (emitter electrode) of the switching element 60, and serves as an emitter terminal. The bonding wire 502 is bonded to the second electrode 62 of the switching element 60 and the lead 403. As a result, the lead 403 is electrically connected to the second electrode 62 (gate electrode) of the switching element 60, and serves as a gate terminal.

According to the present embodiment, the semiconductor device A60 includes the metal plate 49 provided between the lead 401 and the switching element 60. This increases the thermal capacity of the semiconductor device A60 as compared to the configuration without the metal plate 49. As a result, the heat dissipation capability (dynamic heat dissipation capability) of the semiconductor device A60 is improved. Since the metal plate 49 is simply bonded to the lead 401, the size of the lead 401 does not change as viewed in the z direction. Furthermore, the first dimension T1 of the metal plate 49 is set such that the dimension T3 is smaller than the dimension T4 by at least a predetermined dimension. As such, the dimension of the sealing resin 7 in the z direction does not change. This allows the semiconductor device A60 to have the same external dimensions as the one without the metal plate 49.

According to the present embodiment, the lead 401 includes the groove 401c. The groove 401c prevents the melted solder paste 92 from spreading too much on the obverse surface 401a in the electronic component mounting step (S20). This prevents excessive displacement of the metal plate 49 arranged on the obverse surface 401a. Furthermore, the semiconductor device A60 has advantages similar to the semiconductor device A10 owing to its common configuration with the semiconductor device A10.

According to the first to fifth embodiments, the semiconductor devices A10, A20, A30, A40, and A50 are igniters, and according to the sixth embodiment, the semiconductor device A60 is a DFN package only including the switching element 60. However, the present disclosure is not limited to these examples. The semiconductor device according to the present disclosure may include other semiconductor elements, and may be provided in a different package.

The semiconductor device, the ignition device, and the method for manufacturing the semiconductor device according to the present disclosure are not limited to those in the above embodiments. Various design changes can be made to the specific configurations of the elements of the semiconductor device and the ignition device according to the present disclosure, and to the specific processes in the operations of the method for manufacturing the semiconductor device according to the present disclosure.

The present disclosure includes embodiments described in the following clauses.

Clause 1.

A semiconductor device comprising:
a switching element (60);
a first lead (41) including a lead obverse surface (411a) on which the switching element is mounted, and a lead reverse surface (411b) facing away from the lead obverse surface in a thickness direction; and
a metal plate (49) overlapping with the switching element as viewed in the thickness direction and being bonded to the first lead.

Clause 2.

The semiconductor device according to clause 1, wherein the metal plate is provided between the switching element and the first lead.

Clause 3. (First Embodiment, FIG. 5)

The semiconductor device according to clause 2, wherein the first lead has a lead groove (411c) that is recessed from the lead obverse surface in the thickness direction, and that surrounds the metal plate as viewed in the thickness direction.

Clause 4. (Third Embodiment, FIG. 15)

The semiconductor device according to clause 2,
wherein the first lead includes a lead recess (411d) recessed from the lead obverse surface in the thickness direction, and
the metal plate is arranged in the lead recess.

Clause 5. (Fourth Embodiment, FIG. 16)

The semiconductor device according to any of clauses 2 to 4, wherein the metal plate includes a metal-plate obverse surface (49a) facing a same side as the lead obverse surface in the thickness direction, and a metal-plate groove (49c) recessed from the metal-plate obverse surface and surrounding the switching element as viewed in the thickness direction.

Clause 6. (Fifth Embodiment, FIG. 17)

The semiconductor device according to any of clauses 2 to 4,
wherein the metal plate includes a metal-plate obverse surface facing a same side as the lead obverse surface in the thickness direction, and a metal-plate recess (49d) recessed from the metal-plate obverse surface in the thickness direction, and
the switching element is arranged in the metal-plate recess.

Clause 7. (Second Embodiment, FIG. 14)

The semiconductor device according to clause 1, wherein the metal plate is arranged on the lead reverse surface.

Clause 8.

The semiconductor device according to any of clauses 1 to 7, wherein the metal plate contains Cu.

Clause 8-1.

The semiconductor device according to clause 8, wherein both surfaces of the metal plate facing in the thickness direction are provided with metal layers containing Ni.

Clause 9. (FIG. 5)

The semiconductor device according to any of clauses 1 to 8, wherein a first dimension (T1) of the metal plate in the thickness direction is at least 80% and at most 150% of a second dimension (T2) of the first lead in the thickness direction.

Clause 10.

The semiconductor device according to clause 9, wherein the first dimension is at least 0.5 mm and at most 0.7 mm.

Clause 11.

The semiconductor device according to any of clauses 1 to 10, wherein as viewed in the thickness direction, a first area (S1) of the metal plate is at least 100% and at most 120% of a second area (S2) of the switching element.

Clause 11-1.

The semiconductor device according to clause 11, wherein as viewed in the thickness direction, the first area (S1) of the metal plate is at least 30% and at most 80% of a third area (S3) of the first lead.

Clause 12.

The semiconductor device according to any of clauses 1 to 11, wherein as viewed in the thickness direction, a second area (S2) of the switching element is at least 30% and at most 80% of a third area (S3) of the first lead.

Clause 12-1.

The semiconductor device according to any of clauses 1 to 12, wherein the switching element is an IGBT.

Clause 13.

The semiconductor device according to any of clauses 1 to 12, further comprising:
a control element (20) that controls the switching element; and
a second lead (42) on which the control element is mounted.

Clause 14. (FIG. 1)

An ignition device comprising:
the semiconductor device according to clause 13; and
an ignition coil (4) including a primary coil (4a) electrically connected to the first lead,
wherein the control element (13) is configured to drive the switching element (11) according to an ignition command signal (IGT) inputted from an engine control device (2).

Clause 15. (FIG. 7)

A method for manufacturing a semiconductor device, comprising:
applying first solder paste (92) to a lead frame (91) (S21);
placing a passive component and a metal plate on the first solder paste (S22);
applying second solder paste (93) to the metal plate (S23);
placing a switching element on the second solder paste (S24); and
melting and then solidifying the first solder paste and the second solder paste (S25).

### REFERENCE NUMERALS

A10, A20, A30, A40, A50, A60: Semiconductor device
11: Switching element 12: Current sensing resistor
13: Control circuit 133: Drive unit
134: Ignition confirmation unit
FB: Feedback terminal GND: Ground terminal
IN: Input terminal OUT: Output terminal
VDD: Power supply terminal
2: ECU 3: Spark plug 4: Ignition coil
4a: Primary coil a 4b: Secondary coil 5: Battery
B: Vehicle 20: Control element
20a: Element obverse surface
20b: Element reverse surface 21: Power supply pad
22: Ground pad 23: Input pad 24: Gate output pad
25: Feedback output pad 26: Sense input pad
27: Sense ground pad 41-48, 401-403: Lead
411, 421, 481: Mount portion 441, 451, 461: Pad portion
411a, 421a, 401a: Obverse surface
411b, 421b, 401b: Reverse surface
411c, 421c, 401c: Groove 411d: Recess
412, 422, 442, 452, 462, 482: Terminal portion
49: Metal plate 49a: Obverse surface 49b: Reverse surface
49c: Groove 49d: Recess
51-59, 501, 502: Bonding wire 60: Switching element
60a: Element obverse surface 60b: Element reverse surface
61: First electrode 62: Second electrode
63: Third electrode 7: Sealing resin
71: Resin obverse surface
72: Resin reverse surface 73-76: Resin side surface
81, 82: Bonding member 14, 16: Capacitor
15: Resistor 91: Lead frame
91a: Obverse surface 91b: Reverse surface
92, 93: Solder paste

1. A semiconductor device comprising:
a switching element;
a first lead including a lead obverse surface on which the switching element is mounted, and a lead reverse surface facing away from the lead obverse surface in a thickness direction; and
a metal plate overlapping with the switching element as viewed in the thickness direction and being bonded to the first lead.

2. The semiconductive device according to claim 1, wherein the metal plate is provided between the switching element and the first lead.

3. The semiconductive device according to claim 2, wherein the first lead has a lead groove that is recessed from the lead obverse surface in the thickness direction, and that surrounds the metal plate as viewed in the thickness direction.

4. The semiconductive device according to claim 2, wherein the first lead includes a lead recess recessed from the lead obverse surface in the thickness direction, and
the metal plate is arranged in the lead recess.

5. The semiconductive device according to claim 2, wherein the metal plate includes a metal-plate obverse surface facing a same side as the lead obverse surface in the thickness direction, and a metal-plate groove recessed from the metal-plate obverse surface and surrounding the switching element as viewed in the thickness direction.

6. The semiconductive device according to claim 2, wherein the metal plate includes a metal-plate obverse surface facing a same side as the lead obverse surface in the thickness direction, and a metal-plate recess recessed from the metal-plate obverse surface in the thickness direction, and
the switching element is arranged in the metal-plate recess.

7. The semiconductive device according to claim 1, wherein the metal plate is arranged on the lead reverse surface.

8. The semiconductive device according to claim 1, wherein the metal plate contains Cu.

9. The semiconductive device according to claim 1, wherein a first dimension of the metal plate in the thickness direction is at least 80% and at most 150% of a second dimension of the first lead in the thickness direction.

10. The semiconductive device according to claim 9, wherein the first dimension is at least 0.5 mm and at most 0.7 mm.

11. The semiconductive device according to claim 1, wherein as viewed in the thickness direction, a first area of the metal plate is at least 100% and at most 120% of a second area of the switching element.

12. The semiconductive device according to claim 1, wherein as viewed in the thickness direction, a second area of the switching element is at least 30% and at most 80% of a third area of the first lead.

13. The semiconductive device according to claim 1, further comprising:
a control element that controls the switching element; and
a second lead on which the control element is mounted.

14. An ignition device comprising:
a semiconductive device according to claim 13; and
an ignition coil including a primary coil electrically connected to the first lead,
wherein the control element is configured to drive the switching element according to an ignition command signal inputted from an engine control device.

15. A method for manufacturing a semiconductive device, comprising:
applying first solder paste to a lead frame;
placing a passive component and a metal plate on the first solder paste;
applying second solder paste to the metal plate;
placing a switching element on the second solder paste; and
melting and then solidifying the first solder paste and the second solder paste.
